(19) United States
(12) Patent Application Publication
(10) Pub. No.: US 2007/0128860 A1
(43) Pub. Date: Jun. 7, 2007

(54) Method and apparatus for improving breakdown voltage of integrated circuits formed using a dielectric layer process

(75) Inventors: Kuan Cheng Hou, Shanghai (CN); Shou Long Lan, Shanghai (CN); Rui Dong, Shanghai (CN); Ting Cheong Ang, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 11/320,871

(22) Filed: Dec. 28, 2005

(30) Foreign Application Priority Data
Dec. 5, 2005 (CN) 200510111131.8

(51) Int. Cl. H01L 21/44; C23C 16/00

(52) U.S. Cl. 438/680; 118/715

(57) ABSTRACT

A method and apparatus for depositing a dielectric layer. The apparatus includes a semiconductor processing chamber configured for use in a dielectric layer deposition process, the semiconductor processing chamber being associated with at least a length, a width, a height, and a volume, one or more gas sources containing one or more gases used in the barrier layer deposition process, and one or more gas flow controllers coupled to the one or more gas sources, the one or more gas flow controllers configured to provide one or more controlled amounts of one or more gas flows to the semiconductor processing chamber during semiconductor processing. One or more gas lines coupled to the one or more gas flow controllers for receiving one or more gas flows from the one or more gas flow controllers, and a pumping system is coupled to the semiconductor processing chamber, the pumping system configured to remove a quantity of gas from either the semiconductor processing chamber or the one or more gas lines. A 3-way valve is coupled to the pumping system and the process chamber, the 3-way valve being configured to allow the one or more gas flows to be sent to the pumping system or to the process chamber.

### CROSS-REFERENCES TO RELATED APPLICATIONS

This application claims priority to Chinese Patent Application No. 200510111131.8, filed Dec. 5, 2005, commonly assigned and which is incorporated by reference herein for all purposes.

### BACKGROUND OF THE INVENTION

The present invention is directed to integrated circuits and their processing for the manufacture of semiconductor devices. More particularly, the invention provides a method and apparatus for improving the breakdown voltage of integrated circuits. Merely by way of example, the invention has been applied to a dielectric layer process used in conjunction with a dual damascene structure for signal processing devices. But it would be recognized that the invention has a much broader range of applicability. For example, the invention can be applied to microprocessor devices, logic circuits, application specific integrated circuit devices, as well as various other interconnect structures.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed. An example of such a limit is the breakdown voltage, or the maximum voltage that can be conducted across an insulator before the insulator collapses and conducts electricity. This can cause electrical failure or impaired performance of the circuit. By increasing the breakdown voltage that can be applied to a circuit, the robustness and ability of the circuit to handle high voltages is increased.

From the above, it is seen that a technique for improving the breakdown voltage in a integrated circuit device is desired.

### BRIEF SUMMARY OF THE INVENTION

The present invention is directed to integrated circuits and their processing for the manufacture of semiconductor devices. More particularly, the invention provides a method and apparatus for improving the breakdown voltage of integrated circuits. Merely by way of example, the invention has been applied to a dielectric layer process used in conjunction with a dual damascene structure for signal processing devices. But it would be recognized that the invention has a much broader range of applicability. For example, the invention can be applied to microprocessor devices, logic circuits, application specific integrated circuit devices, as well as various other interconnect structures.

In a specific embodiment, an apparatus for depositing a dielectric layer is provided. The apparatus includes a semiconductor processing chamber configured for use in a dielectric layer deposition process, the semiconductor processing chamber being associated with at least a length, a width, a height, and a volume, one or more gas sources containing one or more gases used in the dielectric layer deposition process, and one or more gas flow controllers coupled to the one or more gas sources, the one or more gas flow controllers configured to provide one or more controlled amounts of one or more gas flows to the semiconductor processing chamber during semiconductor processing. One or more gas lines coupled to the one or more gas flow controllers for receiving one or more gas flows from the one or more gas flow controllers, and a pumping system is coupled to the semiconductor processing chamber, the pumping system configured to remove a quantity of gas from either the semiconductor processing chamber or the one or more gas lines. A 3-way valve is coupled to the pumping system and the process chamber, the 3-way valve being configured to allow the one or more gas flows to be sent to the pumping system or to the process chamber.

In a specific embodiment, a method for forming integrated circuits is disclosed. A method for forming integrated circuits is provided. The method includes providing a semiconductor processing chamber and one or more gas sources, the one or more gas sources each containing a volume of gas. One or more gases is then flowed through one or more gas controllers, the one or more gas controllers being configured to provide an amount of gas flow to the semiconductor processing chamber through at least a gas line, the gas line being coupled to the semiconductor processing chamber. The flow direction of a 3-way valve interposed on the gas line is then set to flow the one or more gases to a pumping system. Subsequently, the flow direction of the 3-way valve is changed from the pumping system to the semiconductor processing chamber, causing the one or more gases to be flowed to the process chamber, and a plasma is generated in the semiconductor processing chamber. A dielectric layer is then deposited using the one or more gases being flowed to the semiconductor processing chamber.

In a specific embodiment, a method for forming integrated circuits is disclosed. A semiconductor processing chamber, one or more gas lines, and one or more gas sources are provided, the gas lines coupled to the semiconductor processing chamber and including an amount of a residual gas remaining from a prior deposition process. The one or more gas sources includes one or more volumes of one or more gases respectively. The one or more gases is then flowed from the one or more gas sources through one or more gas controllers to the one or more gas lines respectively, the one or more gas sources coupled to the one or more gas controllers for regulating the one or more gases being flowed from the one or more gas sources. The flow direction for a 3-way valve is set to a pumping system, the pumping system receiving both the one or more gases from the one or more gas sources as well as the residual gas remaining in the one or more gas lines; The flow direction is then set for the 3-way valve to the semiconductor processing chamber, the one or more gases from the one or more gas sources being flowed into the semiconductor processing chamber. A plasma is then generated in the semiconductor processing chamber; and a dielectric layer is then deposited using the one or more gases being flowed to the semiconductor processing chamber.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. A method and apparatus for improving the breakdown voltage of integrated circuits formed using a barrier layer process is provided. In a specific embodiment, gas flow bursting that occurs due to residual gas left in gas lines from prior deposition processes is prevented from affecting subsequent deposition process. For example, the breakdown voltage of integrated circuits is improved by at least 75% from wafers when bursting does not occur as compared to wafers where bursting occurred. In another example, reduction in bursting when multiple gas lines are used can be achieved. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified conventional method showing processes employed during and immediately after a dual damascene process;

FIG. 2 is a simplified conventional cross-section showing a dual damascene copper structure and a barrier metal layer overlying the copper region;

FIG. 3 is a simplified conventional diagram of a gas delivery mechanism to a semiconductor processing chamber;

FIG. 4 is a simplified exemplary chart showing percent gasflow vs. time for a series of gas flow processes;

FIG. 5 is a simplified exemplary chart showing percent gasflow vs. time for a single gas flow process;

FIG. 6 is a simplified exemplary chart showing median breakdown voltage vs. Q-time;

FIG. 7 is a simplified exemplary diagram of a gas line design for a semiconductor processing chamber according to an embodiment of the present invention;

FIG. 8 is a simplified exemplary flowchart of a gas flow sequence for a semiconductor processing chamber according to an embodiment of the present invention;

FIG. 9 is a simplified exemplary diagram of an alternative gas line design for a semiconductor processing chamber according to another embodiment of the present invention;

FIG. 10 is a simplified exemplary diagram of an alternative gas line design for a semiconductor processing chamber according to yet another embodiment of the present invention;

FIG. 11 is a simplified exemplary chart comparing median breakdown voltage vs. Q-time for wafers according to an embodiment of the present invention; and

FIG. 12 is an simplified exemplary chart comparing % cumulative failure vs. breakdown voltage according to an embodiment of the present invention.

### DETAILED DESCRIPTION OF THE INVENTION

The present invention is directed to integrated circuits and their processing for the manufacture of semiconductor devices. More particularly, the invention provides a method and apparatus for improving the breakdown voltage of integrated circuits. Merely by way of example, the invention has been applied to a dielectric layer process used in conjunction with a dual damascene structure for signal processing devices. But it would be recognized that the invention has a much broader range of applicability. For example, the invention can be applied to microprocessor devices, logic circuits, application specific integrated circuit devices, as well as various other interconnect structures.

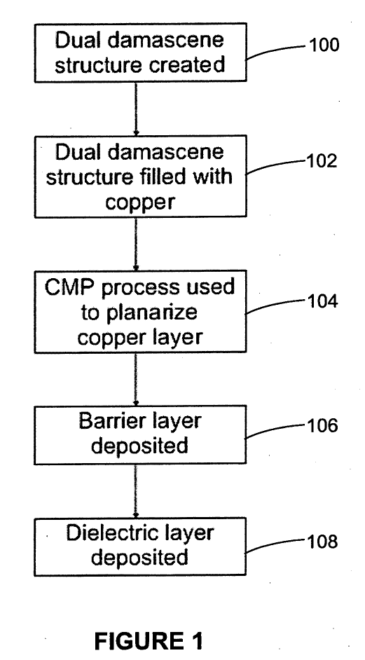

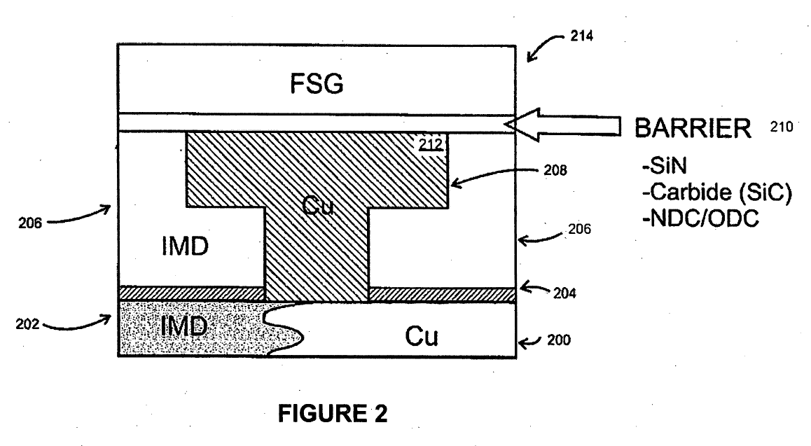

FIG. 1 is a simplified conventional method showing processes employed during and immediately after a dual damascene process. Method 110 includes a process 100 of creating a dual damascene structure, a process 102 for filling the dual damascene structure with copper, a process 104 for planarizing the copper layer, a process 106 for forming a barrier layer, and a process 108 for forming a dielectric layer. FIG. 1 may be more properly understood in regards to FIG. 2, which is a simplified conventional cross-section showing a dual damascene copper structure and a barrier metal layer overlying the copper region.

Copper layer 200 is formed overlying a surface region (not shown) on a semiconductor substrate, where the surface region may comprise any number of layers overlying the semiconductor substrate and is not limited to consist of only one layer. Inter-metal dielectric (IMD) layer 202 may also be present adjacent to copper layer 200. An etch stop layer 204 overlies copper layer 200 and IMD layer 202. Etch stop layer 204 is adjacent to IMD layer 206. A dual damascene structure is created in process 100 by etching a trench and via in IMD layer 206. The dual damascene trench/via may be formed by a variety of possible methods, including via-first approach, a trench-first approach, or by a self-aligned via approach. The trench is lined with a thin layer of barrier metal 208 lining both the via and the trench, and the dual damascene trench and via are filled with copper in process 102. In a specific embodiment, the trench and via may be filled by first depositing a seed layer of copper overlying the barrier metal layer, and plated using an electrochemical plating (ECP) process. A chemical-mechanical polishing (CMP) process can be employed to planarize the copper layer formed by the ECP process. Dielectric layer 210 is deposited in process 106 following the CMP process, overlying copper region 212 as well as IMD layer 206. For example, the dielectric layer may be a barrier layer formed of silicon nitride (SiN), silicon carbide, (SiN), or nitrogen-doped carbide (NDC) or oxygen-doped carbide (ODC). A dielectric layer 214 is deposited over the barrier layer, where an exemplary material used to form the dielectric layer is FSG, or fluorine-doped silicate glass in process 108.

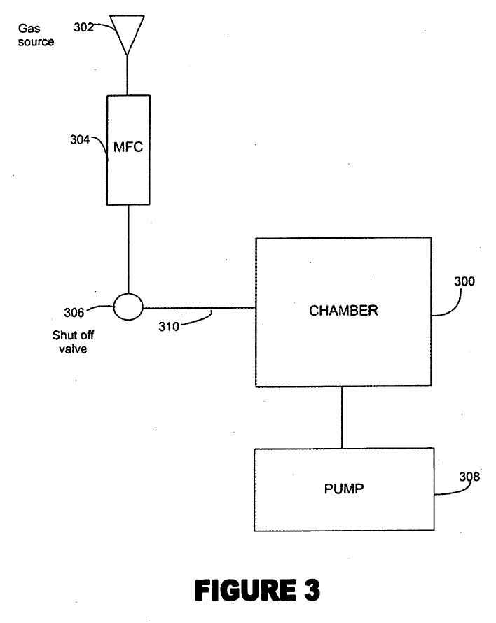

For example, the deposition of barrier layer 210 in process 106 is performed using a chemical vapor deposition (CVD) process. In a typical CVD process, the wafer is exposed to one or more volatile precursors containing atoms of the material to be deposited. The precursors are then reacted with another chemical or treated to produce the desired material. Byproducts of the deposition process may be removed from the deposition chamber after the deposition process has concluded. In a specific embodiment, the precursor used may be a gaseous material such as silane (SiH₄) which is used in the chemical vapor deposition (CVD) of silicon dioxide, silicon nitride, polysilicon, epitaxial silicon and amorphous silicon films. The precursor material is typically introduced to the semiconductor processing chamber through a gas delivery mechanism. FIG. 3 is a simplified conventional diagram of a gas delivery mechanism to a semiconductor processing chamber. Gas source 302 contains the specific gas to be introduced to semiconductor processing chamber 300. Mass flow controller (MFC) 304 is coupled with gas source 302 at one end and is used to regulate the amount of gas flow entering the semiconductor processing chamber. Multiple MFC's may be employed to direct different types of gas to the chamber. Shutoff valve 306 is interposed on gasline 310 between MFC 304 and chamber 300 and either restricts or allows the flow of gas to proceed into semiconductor processing chamber 300. Shutoff valve 306 may be actuated by a pneumatic valve or other controlling means. The flow of gas from gas source 302 and MFC 304 is received and distributed within chamber 300. Pump system 308 is coupled to chamber 300 and can be used to remove volatile byproducts of the CVD reaction from chamber 300.

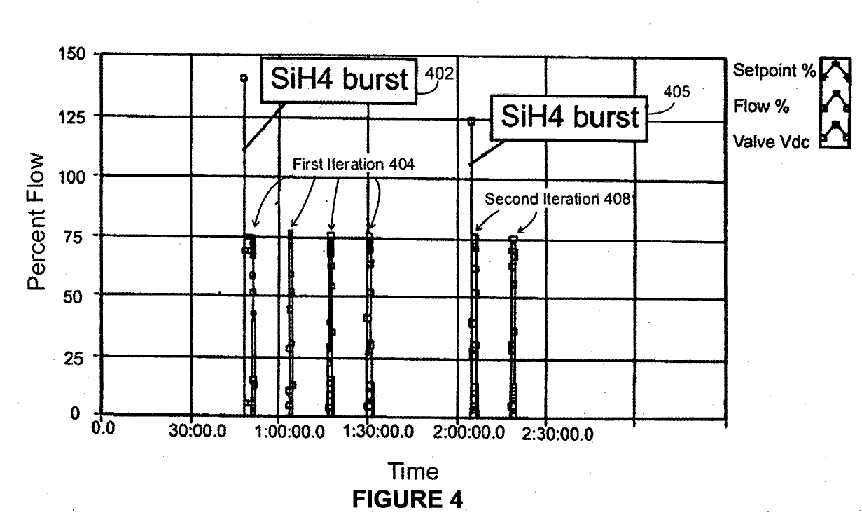

One problem that occurs during gas flow delivery to chamber is that bursting can occur within the delivery of gas to the wafer, especially during a startup period when gas is beginning to flow. Gas flow to the chamber is not continuously maintained after a deposition process has been concluded and the flow of gas often needs to be restarted when a subsequent deposition process is to be performed. This can cause a greater amount of gas to be delivered than requested following a period when no gas has been flowed for a period of time. This can be seen in FIG. 4 which is a simplified exemplary chart showing percent gasflow vs. time for a series of gas flow processes. This diagram is merely an example, which should not unduly limit the scope of the claims herein. One of ordinary skill in the art would recognize many variations, modifications, and alternatives. Initial gas flow 402 is one of several instances of gas flow within the first iteration of gas flows 404. In a specific embodiment, gas flows 402, 404, 406, and 408 may be gas flows during when deposition of a layer occurs using the gas being flowed. The requested amount of gas flow or setpoint for first requested gas flow 402 is 75% flow of the MFC, but the actual flow was closer to 140% flow, much higher than requested. A 100% gasflow typically represents the maximum amount of gas flow which can be regulated by the MFC within tolerance boundaries. For example, a 200 sccm rated MFC may be able to flow more than 200 sccm, but may not be able to repeatedly flow the specified amount of gas within the tolerance (typically +−5% of the setpoint) or reach the setpoint requested by the user or program. Subsequent gas flow processes within first iteration 404 do not exhibit this pattern where the actual flow percentage differs significantly from the setpoint percentage. A gap of time exists between first iteration 404 and second iteration 408 of gas flows. Similarly, second initial flow 406 has an actual flow percentage much higher than that of the requested setpoint. The following gas flow point after second initial flow 406 does not exhibit a large difference between the setpoint and the actual flow percentage. Of course, there can be other variations, modifications, and alternatives.

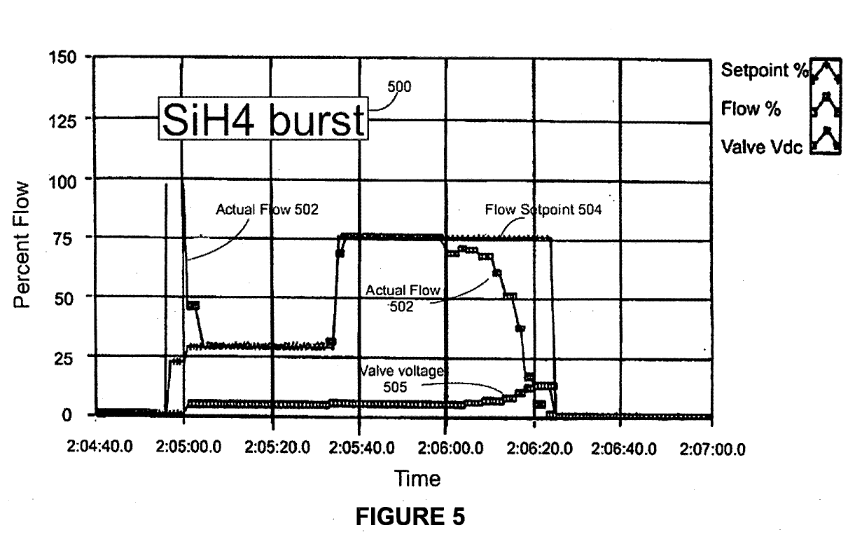

FIG. 5 is a simplified exemplary chart showing percent gasflow vs. time for a single gas flow process where the time domain has been expanded to show the gas flow operation in greater detail. This diagram is merely an example, which should not unduly limit the scope of the claims herein. One of ordinary skill in the art would recognize many variations, modifications, and alternatives. During the gas flow process shown in FIG. 5, the flow setpoint 504 of the gas is initially low near the 25% mark for a period and then rises to 75%. However, the actual flow 502 of the gas rises dramatically during the 25% setpoint period to flow near 125% of the MFC capacity for a short period in SiH₄ burst 500. The actual flow percentage stabilizes soon after the initial burst period and matches the setpoint for a period before gradually decreasing. In a specific embodiment of the invention, silane may be the gas being flowed. Valve voltage 506 is also shown within FIG. 5, where the valve voltage represents the voltage being applied to the controlling valve within the MFC that allows the gas to be flowed. Without being limited by an explanation, valve voltage 506 may be low during the initial bursting period 500 because of poor control due to the large amount of gas coming in. Of course, there can be other variations, modifications, and alternatives.

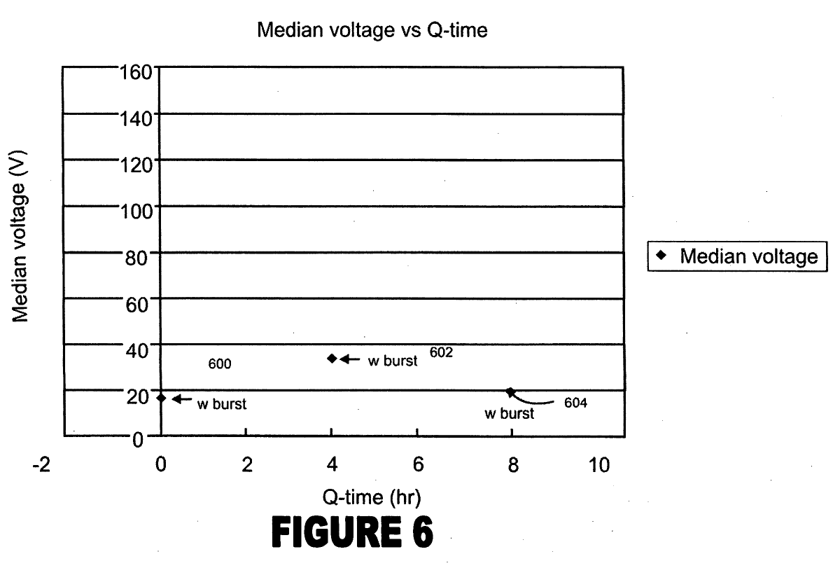

One specific problem that can occur during the dual damascene process described in FIG. 1 as a result of bursting is that the amount of precursor gas being delivered to the semiconductor processing chamber is not uniform. This can result in improper deposition of the CVD layer or cause formation of other unwanted materials on the surface of the wafer. Without being limited to an explanation, the bursting that can occur when silane is used as a precursor gas for a deposition process can cause a conductive copper silicide to be formed, which decreases the breakdown voltage of the device. In a specific embodiment, the silicide is formed by the silane gas interacting with the exposed copper regions on the wafer. The effect of the silicide region upon the breakdown voltage of the device can be seen in FIG. 6, which is a simplified exemplary chart showing median breakdown voltage vs. Q-time. This diagram is merely an example, which should not unduly limit the scope of the claims herein. One of ordinary skill in the art would recognize many variations, modifications, and alternatives. Within the scope of this application, Q-time is defined as the time in between subsequent processes. A complicated fabrication sequence such as that used in the formation of a dual damascene structure can involve numerous processes and a significant delay may occur in between subsequent processes, as the semiconductor manufacturing equipment may not be ready to immediately process the wafers. For example, Q-time may be the time between CMP and a subsequent dielectric layer deposition process. In general, longer time between processes yields a lower breakdown voltage because conductive oxide layers such as copper oxide can develop on top of copper layer due to exposure to air between processes. In a specific embodiment, the wafers may be contained within sealed processing environments such as Front Opening Unified Pods (FOUPs) in between processes, but the wafers are still subject to the ambient environment within the sealed processing environment and oxidation may still occur on the wafer. Data points 600, 602, and 604 compare breakdown voltages for a variety of Q-times. Data point 600 shows a Q-time of 0, meaning that the wafer was immediately processed between the CMP and barrier layer deposition processes, while for data point 604 the Q-time was 8 hours between processes. It can be seen that the breakdown voltages for all three data points where bursting is occurring is low, as the breakdown voltage of the device is less than 40V. Breakdown voltages of at least 60-80V are desired to increase the reliability and robustness of the device being formed. Of course, there can be other variations, modifications, and alternatives.

Without being limited by an explanation, one possible reason for why bursting can lead to a lower breakdown voltage is that residual gas is accumulated within the gas line between the MFC and semiconductor processing chamber after a process ends. As a result, there may be a quantity of gas present within the gas line from prior deposition processes. Subsequent gas flow from the MFC and gas source during a deposition process may result in a greater amount of gas being deposited as the requested amount of gas from the MFC and the residual gas from previous deposition processes is sent to the chamber. Of course, there can be other variations, modifications, and alternatives.

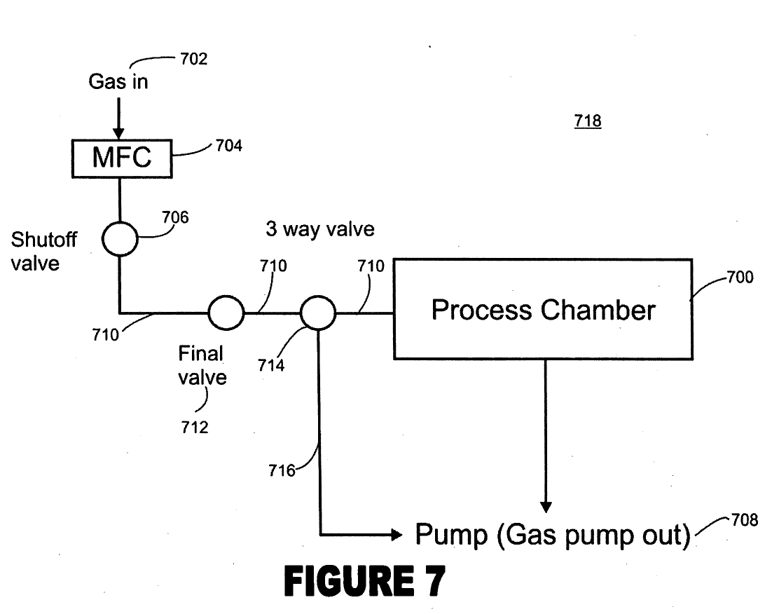

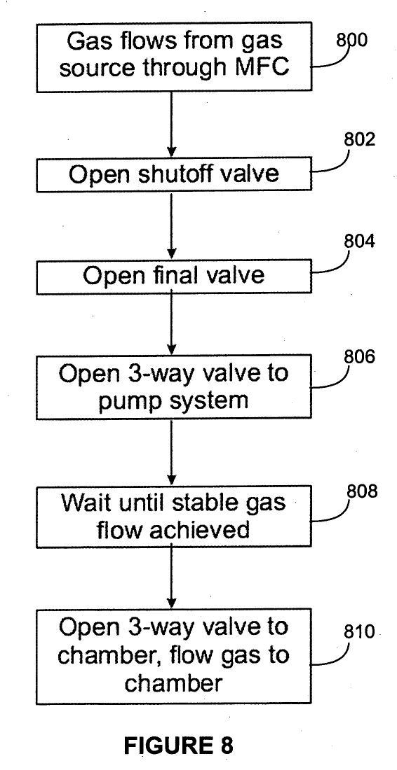

FIG. 7 is a simplified exemplary diagram of a gas line design for a semiconductor processing chamber according to an embodiment of the present invention. For example, FIG. 7 may be better understood in conjunction with FIG. 8, which is a simplified exemplary flowchart of a gas flow sequence for a semiconductor processing chamber according to an embodiment of the present invention. The sequence 812 includes a process 800 for flowing gas from a gas source through a MFC, a process 802 for opening a shutoff valve, a process 804 for opening a final valve, a process 806 for opening a 3-way valve to a pump system, a process 808 for waiting until a stable gas flow is achieved, and process 810 for opening a 3-way valve to the chamber and flowing gas to the chamber. These diagrams are merely examples, which should not unduly limit the scope of the claims herein. One of ordinary skill in the art would recognize many variations, modifications, and alternatives.

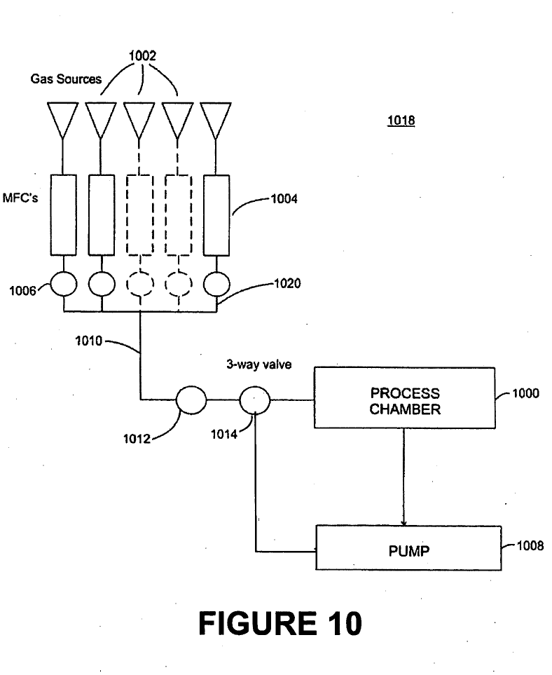

In process 800, gas is flowed from gas source 702 through a gas flow controller such as MFC 704, which regulates the amount of gas flow from the gas source 702 to semiconductor processing chamber 700. In a specific embodiment, multiple MFC's may be employed to direct different types of gas to the chamber. Shutoff valve 706 is opened is opened in process 802 to enable the flow of gas from the MFC through gas line 710. Final valve 712 is opened in process 804 to further allow gas flow through gas line 710. Final valve 712 may be employed to provide additional flow controls for the flow of gas into semiconductor processing chamber 700 or may be employed as a valve control when multiple MFC's and gas flows are directed into the chamber. A specific embodiment of the present invention describing multiple MFC's and gas flows into semiconductor chamber 700 will be discussed in more detail with respect to FIG. 10. For example, if only one gas is being used in semiconductor processing system 718, final valve 712 can be removed. A three-way valve 714 is interposed on gas line 710 between final valve 712 and semiconductor processing chamber 700. Pumping system 708 is coupled to both semiconductor processing chamber 700 and 3-way valve 714. In a specific embodiment, pumping system 708 can be used either to remove excess gas or contaminants in gasline 710 from entering semiconductor processing chamber 700, or remove gas or contaminants from the semiconductor processing chamber 700 after a process sequence has been concluded. The pumping system may be implemented in a variety of different embodiments. In a specific embodiment, the pumping system may be implemented as a turbopump, which may be located near semiconductor processing chamber 700. In a specific embodiment, the pumping system may be implemented as a cryopump, which may be located near semiconductor processing chamber 700. In a specific embodiment, the pumping system may be implemented as a roughing pump or equivalent pump located in the semiconductor facility. In a specific embodiment, a combination of the different pumping methods may be used. For example, a roughing pump and cryopump can be used in conjunction as pumping system 708. Of course, there can be other variations, modifications, and alternatives.

In process 806, 3-way valve 714 is opened to pumping system 708. A 3-way valve is designed with an input opening and two output openings. The valve can be controlled to set the flow direction of 3-way valve 714 to one of the output openings. Only one output opening may be open at any point in time. In a specific embodiment, the 3-way valve may be pneumatically or electrically controlled. In another specific embodiment, 3-way valve 714 possesses an input opening from gas line 710 and has two output openings coupled to semiconductor processing chamber 700 and pumping system 708. Of course, there can be other variations, modifications, and alternatives.

When 3-way valve 714 is opened to pumping system 708 in process 806, residual gas existing in gas line 710 that has accumulated between MFC 704 and semiconductor processing chamber 700 can be removed prior to the gas being flowed into the chamber. In a specific embodiment, 3-way valve 714 is configured to allow the gas flows in gas line 710 to be pumped in process 808 to pumping system 708 until stable gas flows can be achieved. In another specific embodiment, the gas flows becomes stable within a predetermined period of gas flow. The amount of time can be empirically determined using testing and will vary for the specific gas and components used in semiconductor processing system 718. By pumping gas line 710 prior to allowing the gas to enter the process chamber, a stable gas flow can be achieved by removing the residual amount of gas existing within gas line 710. This prevents bursting from occurring during a subsequent deposition process. In yet another specific embodiment, a monitoring device can be placed in gas line 710 to monitor the amount of gas flowing in gas line 710 to ensure a stable gas flow is achieved prior to deposition. Of course, there can be other variations, modifications, and alternatives.

Once a stable gas flow has been achieved in process 808, 3-way valve 714 is opened to semiconductor processing chamber 700 and gas is flowed to chamber 700 in process 810. This can be performed by setting the flow direction of 3-way valve 714 to the semiconductor processing chamber 700. In a specific embodiment, the gas is a precursor used in the deposition of a layer or film upon a wafer. In another specific embodiment, the gas being flowed is silane, and a dielectric layer such as a diffusion barrier is being deposited. In yet another specific embodiment, the dielectric layer or diffusion barrier may be used in a dual-damascene process. In yet another specific embodiment, 3-way valve 714 is configured to allow the gas flows in gas line 710 to be sent to semiconductor processing chamber 700 after the gas flows become stable. Of course, there can be other variations, modifications, and alternatives.

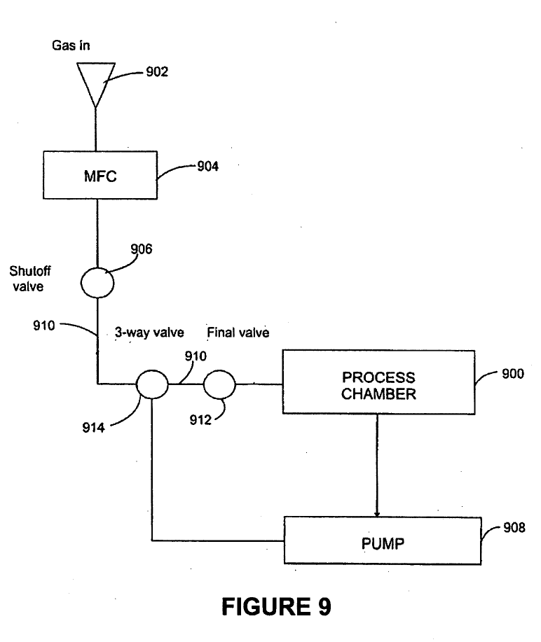

FIG. 9 is a simplified exemplary diagram of a gas line design for a semiconductor processing chamber according to another embodiment of the present invention. This diagram is merely an example, which should not unduly limit the scope of the claims herein. One of ordinary skill in the art would recognize many variations, modifications, and alternatives. Many of the components used in FIG. 9 are similar to those used in FIG. 7 and their description will not be repeated herein. 3-way valve 914 has been implemented on gas line 910 between shutoff valve 906 and final valve 912. This configuration also allows for residual gas existing within gas line 910 to be pumped and removed from the system prior to deposition. Final valve 912 can be further used as a control mechanism to allow or prevent gas flow from entering process chamber 900. Of course, there can be other variations, modifications, and alternatives.

FIG. 10 is a simplified exemplary diagram of a gas line design for a semiconductor processing chamber according to yet another embodiment of the present invention. This diagram is merely an example, which should not unduly limit the scope of the claims herein. One of ordinary skill in the art would recognize many variations, modifications, and alternatives. In semiconductor processing equipment, it is common to utilize many different kinds of gases within a semiconductor processing chamber for different purposes. Thus, it would also be advantageous to develop a gas line design which could accommodate multiple gas lines which also prevented bursting from occurring in a deposition process. Many of the components used in FIG. 10 are similar to those used in FIG. 7 and their description will not be repeated herein. Multiple gas sources 1002 are coupled to MFC's 1004 which regulate the amount of gas flow from gas sources 1002. Gas sources 1002 are not necessarily connected to MFC's 1004 in a one-to-one connection mapping. For example, one of gas sources 1002 may be connected to two different MFC's 1004 to provided different flow capacities for the gases being flowed. Shutoff valves 1006 are interposed on gas lines 1020 to prevent or allow the flow of gas to proceed further towards semiconductor processing chamber 1000. In another specific embodiment, gas lines 1020 are merged into one gas line 1010 which receives the gas flows from MFC's 1004 in one gas line. Single gas line 1010 is connected to final valve 1012, which controls the flow of gases from MFC's 1004. Final valve 1012 provides an additional flow control whereby the gas flowing through gas line 1010 can be stopped by closing only one valve, instead of having to close shutoff valves 1006 of all the gases being flowed. A 3-way valve 1014 is interposed on gas line 1010 between final valve 1012 and semiconductor processing chamber 1000. Pumping system 1008 is coupled to both semiconductor processing chamber 1000 and 3-way valve 1014. 3-way valve 1014 is configured to allow the gas flows to be sent to the pumping system or chamber, and is initially opened to pumping system 1008 which removes any residual gas that has accumulated between MFC 1004 and semiconductor processing chamber 1000. The flow direction of 3-way valve 1014 is set to send gas flows to pumping system 1008 until the gas flows become stable, which may happen within a predetermined period of gas flow. The flow direction of 3-way valve 1014 can then be changed to cause the gas to be flowed to semiconductor processing chamber 1000. Following gas flow, a plasma can be generated in semiconductor processing chamber 1000 and a dielectric layer deposited using the gases being flowed to semiconductor processing chamber 1000. This allows a stable gas flow to be achieved for a deposition process without bursting occurring during a deposition process. Of course, there can be other variations, modifications, and alternatives.

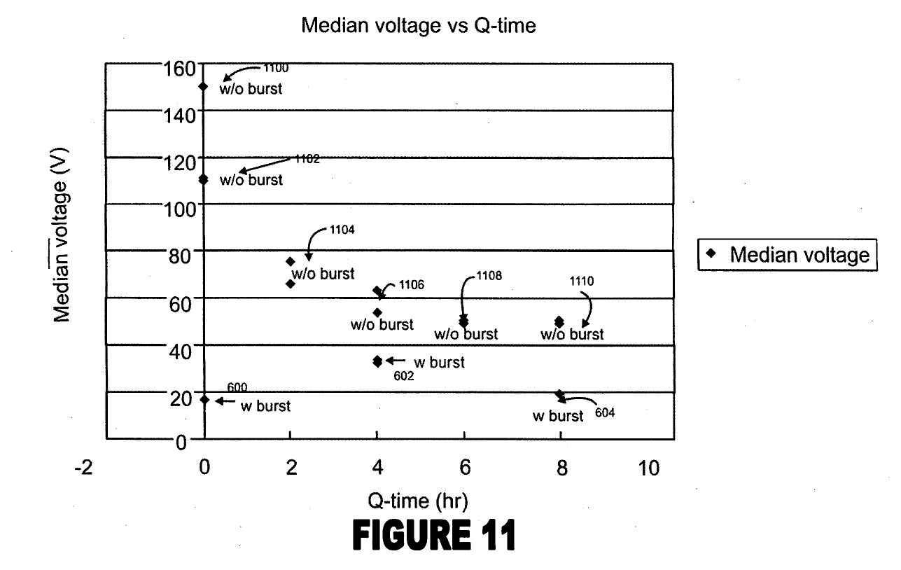

FIG. 11 is a simplified exemplary chart comparing median breakdown voltage vs. Q-time according to an embodiment of the present invention. This diagram is merely an example, which should not unduly limit the scope of the claims herein. One of ordinary skill in the art would recognize many variations, modifications, and alternatives. Data points 600, 602, and 604 are present showing points where bursting occurred, while data points 1100-1110 are data points showing the breakdown voltage for a variety of Q-times when bursting did not occur. Breakdown voltages for data points without bursting are noticeably higher than those where bursting occurred. Additionally, greater amounts of time between processes also yielded lower breakdown voltages. Data points 1100 and 1102 exhibited the breakdown voltages of above 100V, while data point 1110 with a Q-time of 8 hours possessed a breakdown voltage of above 50V. It can be seen that a significant increase in breakdown voltage is achieved when bursting does not occur in the delivery of gases to the semiconductor processing chamber. In an exemplary embodiment, the breakdown voltage of the wafers where bursting does not occur increases by at least 75%. Of course, there can be other variations, modifications, and alternatives.

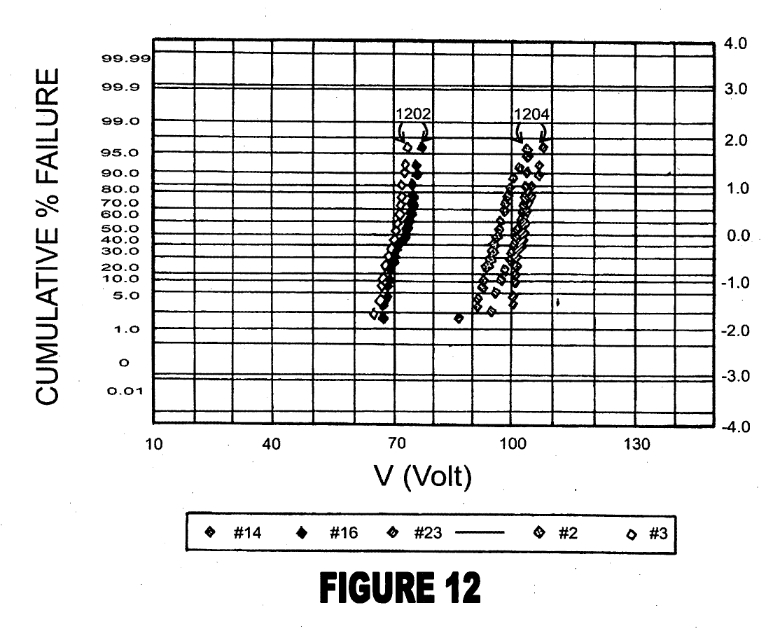

FIG. 12 is an simplified exemplary chart comparing % cumulative failure vs. breakdown voltage according to an embodiment of the present invention. This diagram is merely an example, which should not unduly limit the scope of the claims herein. One of ordinary skill in the art would recognize many variations, modifications, and alternatives. Data sets 1202 represent the set of wafers where bursting occurs and data sets 1204 represent the set of wafers where bursting does not occur. The wafers for which bursting did not occur exhibit a much higher breakdown voltage for similar failure percentages. For example, a wafer which is subjected to approximately 70 volts exhibits a cumulative failure percentage of 5%, while a wafer subjected to between 90-100 volts exhibits a similar cumulative failure percentage of 5%. It can be seen from this chart that wafers that do not exhibit bursting possess a higher breakdown voltage. In an exemplary embodiment, the breakdown voltage of the wafers where bursting does not occur increases by at least 75%. Of course, there can be other variations, modifications, and alternatives.

While specific embodiments have been discussed specifically in regards to a diffusion barrier layer deposition process, the method and apparatus described herein could also be applied to other semiconductor processes where a controlled flow of gas is desired and bursting could occur with a detrimental effect upon wafer performance or reliability.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. An apparatus for depositing a dielectric layer, the apparatus comprising:
a semiconductor processing chamber configured for use in a dielectric layer deposition process, the semiconductor processing chamber being associated with at least a length, a width, a height, and a volume;
one or more gas sources containing one or more gases used in the dielectric layer deposition process;
one or more gas flow controllers coupled to the one or more gas sources, the one or more gas flow controllers configured to provide one or more controlled amounts of one or more gas flows to the semiconductor processing chamber during semiconductor processing;
one or more gas lines coupled to the one or more gas flow controllers for receiving one or more gas flows from the one or more gas flow controllers;
a pumping system coupled to the semiconductor processing chamber, the pumping system configured to remove a quantity of gas from either the semiconductor processing chamber or the one or more gas lines; and
a 3-way valve coupled to the pumping system and the semiconductor processing chamber, the 3-way valve being configured to allow the one or more gas flows to be sent to the pumping system or to the process chamber.

2. The apparatus of claim 1, further comprising one or more shutoff valves interposed on the one or more gas lines, the one or more shutoff valves configured to restrict or allow the one or more gas flows to proceed further through the one or more gas lines.

3. The apparatus of claim 2, and further comprising a final valve interposed between the one or more shutoff valves and the processing chamber to restrict or allow a flow of the one or more gases through the one or more gas lines.

4. The apparatus of claim 3 wherein the one or more gas lines merge into a single gas line before the final valve.

5. The apparatus of claim 1 wherein at least one of the one or more gases is silane.

6. The apparatus of claim 1 wherein the pumping system comprises at least one selected from a group consisting of a roughing pump, a cryopump, and a turbopump.

7. The apparatus of claim 1 wherein the dielectric layer is used as a barrier layer.

8. The apparatus of claim 7 wherein the barrier layer comprises at least one selected from a group consisting of silicon nitride (SiN), silicon carbide (SiC), nitrogen-doped carbide (NDC), and oxygen-doped carbide (ODC).

9. The apparatus of claim 1 wherein the apparatus is used in the formation of a dual-damascene structure.

10. The apparatus of claim 1 wherein the one or more gas controllers is one or more mass flow controllers (MFCs).

11. The apparatus of claim 1 wherein the 3-way valve is configured to allow the one or more gas flows to be sent to the pumping system until the one or more gas flows become stable.

12. The apparatus of claim 11 wherein the one or more gas flows become stable within a predetermined period of gas flow.

13. The apparatus of claim 1 wherein the 3-way valve is configured to allow the one or more gas flows to be sent to the semiconductor processing chamber after the one or more gas flows become stable.

14. The apparatus of claim 1 wherein a length associated with a gas line between the 3-way valve and the semiconductor processing chamber is minimized to reduce an amount of residual gas remaining in the gas line.

15. A method for forming integrated circuits comprising:
providing a semiconductor processing chamber for the manufacture of integrated circuits;
providing one or more gas sources, the one or more gas sources each containing a volume of gas;
flowing one or more gases through one or more gas controllers, the one or more gas controllers being configured to provide an amount of gas flow to the semiconductor processing chamber through at least a gas line, the gas line being coupled to the semiconductor processing chamber;
setting a flow direction of a 3-way valve interposed on the gas line to flow the one or more gases to a pumping system;
changing the flow direction of the 3-way valve from the pumping system to the semiconductor processing chamber, causing the one or more gases to be flowed to the process chamber;
generating a plasma in the semiconductor processing chamber; and
depositing a dielectric layer using the one or more gases being flowed to the semiconductor processing chamber.

16. The method of claim 15, further comprising opening one or more shutoff valves interposed on one or more gas lines.

17. The method of claim 16 wherein a final valve is interposed on the gas line between the one or more shutoff valves and the semiconductor processing chamber to restrict or allow a flow of the one or more gases through the one or more gas lines.

18. The method of claim 17 wherein the one or more gas lines merge into the gas line before the final valve.

19. The method of claim 15 wherein the dielectric layer comprises at least one selected from a group consisting of silicon nitride (SiN), silicon carbide (SiC), nitrogen-doped carbide (NDC), and oxygen-doped carbide (ODC).

20. The method of claim 15 wherein the one or more gases is silane.

21. A method for forming integrated circuits, the method comprising:
providing a semiconductor processing chamber for the manufacture of integrated circuits;
providing one or more gas lines coupled to the semiconductor processing chamber, the one or more gas lines including an amount of a residual gas remaining from a prior deposition process;
providing one or more gas sources including one or more volumes of one or more gases respectively;
flowing the one or more gases from the one or more gas sources through one or more gas controllers to the one or more gas lines respectively, the one or more gas sources coupled to the one or more gas controllers for regulating the one or more gases being flowed from the one or more gas sources;
setting a flow direction for a 3-way valve to a pumping system, the pumping system receiving both the one or more gases from the one or more gas sources as well as the residual gas remaining in the one or more gas lines;
setting the flow direction for the 3-way valve to the semiconductor processing chamber, the one or more gases from the one or more gas sources being flowed into the semiconductor processing chamber;
generating a plasma in the semiconductor processing chamber; and
depositing a dielectric layer using the one or more gases being flowed to the semiconductor processing chamber.
